(19) United States
(12) Patent Application Publication
(10) Pub. No.: US 2012/0104344 A1
(43) Pub. Date: May 3, 2012

(54) SEMICONDUCTOR DEVICE

(75) Inventor: Eiichirou KAKEHASHI, Tokyo (JP)

(73) Assignee: ELPIDA MEMORY, INC., Tokyo (JP)

(21) Appl. No.: 13/272,816

(22) Filed: Oct. 13, 2011

(30) Foreign Application Priority Data
Oct. 28, 2010 (JP) 2010-242186

(51) Int. Cl. H01L 45/00

(52) U.S. Cl. 257/3; 257/E45.002; 257/E45.003

(57) ABSTRACT

A semiconductor device includes a semiconductor element. The semiconductor element comprises a first insulating film, a resistance changing layer, a first electrode, a buried layer, and a second electrode. The first electrode is formed within the opening so as to cover side and bottom surfaces of an inner wall of the opening and so as to include a recessed portion and is in contact with the resistance changing layer via the upper end thereof. The second electrode is formed on the resistance changing layer so as to interpose the resistance changing layer between the second electrode, and the upper end of the first electrode and the buried layer. The semiconductor element changes an electronic resistance between the first and second electrodes by reversibly forming a conductive bridge in the resistance changing layer between the upper end of the first electrode and the second electrode.

This application is based upon and claims the benefit of priority from Japanese Patent Application No. 2010-242186, filed on Oct. 28, 2010, the disclosure of which is incorporated herein in its entirety by reference.

### FIELD OF INVENTION

The present invention relates to a semiconductor device.

### DESCRIPTION OF RELATED ARTS

A reduction in a semiconductor memory device, such as DRAM or flash memory, has been required for the demand for a high integration. As a device size decreases, however, the dimension of electrodes for storing information gets smaller, thereby making it more difficult to store an amount of charge required to reliably operate a memory element. Therefore, a memory element which stores an information amount necessary for operation when size thereof decreases, has been required.

There has been provided, as such a memory element, a memory in which metal ions are dissolved in an ion conductor, a conductive crosslink (hereinafter, may be referred as “conductive bridge”) made of metal, is then formed by having an electrode deposited with the metal ions using the ion conduction of the metal ions and an electrochemical reaction, and then a resistance is changed by short-circuiting or cutting the conductive bridge so that the memory stores information. JP 2002-536840 A, JP 2009-246085 A, JP 2006-173267 A, and IEEE JSSC VOL. 40 NO. 1 P168 disclose such memory. The memory is named an ion conductor memory.

The ion conductor memory element disclosed in JP 2002-536840 A and IEEE JSSC VOL. 40 NO. 1 P168 is designed to hold an ion conductor between two electrodes, either of the electrodes being made of a material including an ion-conductive metallic element. For example, a lower electrode is made of a metallic element which performs ion conduction, and then an ion conductor and an upper electrode are arranged in order above the lower electrode.

Information is kept in memory as a way of a high resistance state (“0” data) or a low resistance state (“1” data) of the resistance between the upper and lower electrodes. The rewriting of information will be explained below. In an initial condition, the resistance between the upper and lower electrodes has a resistance of the ion conductor, which is in a high resistance state. In this state, if a higher voltage is applied to the lower electrode than to the upper electrode, the metal constituting the lower electrode is oxidized, and thus metal ions out of the surface of the lower electrode dissolve in the ion conductor. The metal ions supplied to the ion conductor are reduced by the upper cathodal electrode and deposited as metal. As the deposition advances, a deposited substance reaches from the upper electrode to the lower electrode, and forms a conductive crosslink (conductive bridge) made of the metal. The conductive bridge is made of metal, and the resistance between the upper and lower electrodes becomes small. This state is named a low resistance state (i.e., “1” data) (Writing operation).

Then, a rewrite operation from the low resistance state to the high resistance state is carried out as follows. When a high voltage is applied to the upper electrode than to the lower electrode, the metal constituting the conductive bridge is oxidized, and thus metal-ionized to dissolve into the ion conductor. As the dissolution progresses, the conductive bridge is cut. As such, the resistance between the upper and lower electrodes returns into a high resistance state (i.e., “0” data) (Erasing operation). The conductive bridge may have a width of several nanometers involving approximately a few atoms, and may be a very thin metallic wiring, compared to a processing dimension of current semiconductor manufacturing processes. Since an ion conductor memory stores information on a basis of whether a conductive bridge having such a thin width is connected or severed, the region required to form a memory element may be smaller, and adapted to reduce the memory element in size.

In JP 2009-246085 A and JP 2006-173267, there is disclosed a method in which the ion source is provided with a metallic element of the metal ions between the ion conductor and a lower electrode, and then the metal ions dissolves from the ion source into an ion conductor.

### SUMMARY OF THE INVENTION

In one embodiment, there is provided a semiconductor device including a semiconductor element, comprising:

a first insulating film including an opening which extends inside from a first surface in a thickness direction thereof;

a resistance changing layer formed on the first surface of the first insulating film and including a first ion conductor;

a first electrode formed within the opening so as to cover side and bottom surfaces of an inner wall of the opening and so as to include a recessed portion, the first electrode being in contact with the resistance changing layer via an upper end thereof;

a buried layer filling up the recessed portion of the first electrode and having a higher electronic resistance than the first electrode; and

a second electrode formed on the resistance changing layer so as to interpose the resistance changing layer between the second electrode, and the upper end of the first electrode and the buried layer,

wherein the semiconductor element reversibly forms a conductive bridge in the resistance changing layer between the upper end of the first electrode and the second electrode so as to change an electronic resistance between the first and second electrodes.

In another embodiment, there is provided a semiconductor device including a semiconductor element, comprising:

a first insulating film, a resistance changing layer containing a first ion conductor, and a second electrode formed in this order;

a buried layer filled up inside of the first insulating film so as to interpose the resistance changing layer between the buried layer and the second electrode; and

a first electrode formed in the first insulating film so as to cover side and bottom surfaces of the buried layer which is not in contact with the resistance changing layer, the first electrode being in contact with the resistance changing layer via an upper end thereof and having a lower electronic resistance than the buried layer,

wherein the semiconductor element changes the electronic resistance between the first and second electrodes by reversibly forming a conductive bridge between the upper end of the first electrode and the second electrode within the resistance changing layer.

### BRIEF DESCRIPTION OF DRAWINGS

The above features and advantages of the present invention will be more apparent from the following description of certain preferred embodiments taken in conjunction with the accompanying drawings, in which:

FIG. 1 is a view illustrating one step of method for manufacturing a semiconductor device according to a first exemplary embodiment. FIG. 1B is a plane view of major layers overlapped, and FIG. 1A is a cross-sectional view of the structure of FIG. 1B taken along the line A-A′.

FIG. 2 illustrates one step of method of manufacturing a semiconductor device according to the first exemplary embodiment.

FIG. 3 illustrates one step of method for manufacturing a semiconductor device according to the first exemplary embodiment. FIG. 3B is a top view thereof, and FIG. 3A is a cross-sectional view of the structure of FIG. 3B taken along the line A-A′.

FIG. 4 illustrates one step of method of manufacturing a semiconductor device according to the first exemplary embodiment.

FIG. 5 illustrates one step of method of manufacturing a semiconductor device according to the first exemplary embodiment.

FIG. 6 illustrates one step of method for manufacturing a semiconductor device according to the first exemplary embodiment. FIG. 6B is a top view thereof, and FIG. 6A is a cross-sectional view of the structure of FIG. 6B taken along the line A-A′.

FIG. 7 illustrates one step of method of manufacturing a semiconductor device according to the first exemplary embodiment.

FIG. 8 illustrates one step of method of manufacturing a semiconductor device according to the first exemplary embodiment.

FIG. 9 illustrates one step of method for manufacturing a semiconductor device according to the first exemplary embodiment. FIG. 9B is a top view thereof, and FIG. 9A is a cross-sectional view of the structure of FIG. 9B taken along the line A-A′.

FIG. 10 illustrates one step of method for manufacturing a semiconductor device according to the first exemplary embodiment. FIG. 10B is a top view thereof, and FIG. 10A is a cross-sectional view of the structure of FIG. 10B taken along the line A-A′.

FIG. 11A illustrates one step of method for manufacturing a semiconductor device according to the first exemplary embodiment, and FIG. 11B is a schematic view of a memory cell array of an ion conductor memory element according to the first exemplary embodiment.

FIG. 12 illustrates a rewrite operation in the ion conductor memory element according to the first exemplary embodiment.

FIG. 13 a view of the voltage-current property of the ion conductor memory element when the voltage of a second electrode is swept in the ion conductor memory element according to the first exemplary embodiment.

FIG. 14 illustrates one step of method of manufacturing a semiconductor device according to a second exemplary embodiment.

FIG. 15 illustrates one step of method of manufacturing a semiconductor device according to the second exemplary embodiment.

FIG. 16 illustrates one step of method of manufacturing a semiconductor device according to the second exemplary embodiment.

FIG. 17 illustrates one step of method of manufacturing a semiconductor device according to a third exemplary embodiment.

FIG. 18 illustrates one step of method of manufacturing a semiconductor device according to the third exemplary embodiment.

FIG. 19 illustrates one step of method of manufacturing a semiconductor device according to a fourth exemplary embodiment.

FIG. 20 illustrates one step of method of manufacturing a semiconductor device according to the fourth exemplary embodiment.

FIG. 21 illustrates one step of method of manufacturing a semiconductor device according to the fourth exemplary embodiment.

FIG. 22 illustrates one step of method of manufacturing a semiconductor device according to the fourth exemplary embodiment.

FIG. 23 illustrates one step of method of manufacturing a semiconductor device according to a fifth exemplary embodiment.

FIG. 24 illustrates one step of method of manufacturing a semiconductor device according to the fifth exemplary embodiment.

FIG. 25 illustrates one step of method of manufacturing a semiconductor device according to the fifth exemplary embodiment.

FIG. 26 illustrates a rewrite operation in the ion conductor memory element according to the fifth exemplary embodiment.

In the drawings, reference numerals have the following meanings: 11; semiconductor substrate, 12; element isolation film, 13; device forming region, 14; gate insulating film, 15; gate conductive film, 16; gate shield film, 17; gate electrode, 18; source/drain regions, 19; side wall, 20; gate interlayer film, 21; cell contact plug, 22; cell contact plug interlayer film, 23; source line contact plug, 24; source line, 25; source line interlayer film, 26; device contact plug, 121; device interlayer film, 131; first resist mask, 132; first resist mask opening, 133; element opening, 141, 291, 331; first electrode film, 151, 251, 332; buried layer, 161, 241, 341; first electrode, 161 a, 241 a, 301 a, 341 a; upper end of first electrode, 162, 261, 302, 342; buried layer, 171, 311; resistance changing layer, 181, 312; second electrode film, 182; second electrode mask film, 191, 321, 351; resistance changing layer, 192, 322, 352; second electrode, 193; second electrode mask, 201, 323; second electrode interlayer film, 202, 324; bit line contact plug, 203, 325; bit line, 211; bit line interlayer film, 212; upper wiring, 221; separated product (Extracted product), 222, 363; conductive bridge, BLj; bit line, Mij; memory element, SLj; source line, Trij; selective transistor, VB; voltage of first electrode, VU; voltage of second electrode, WLi; word line

### DETAILED DESCRIPTION OF REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

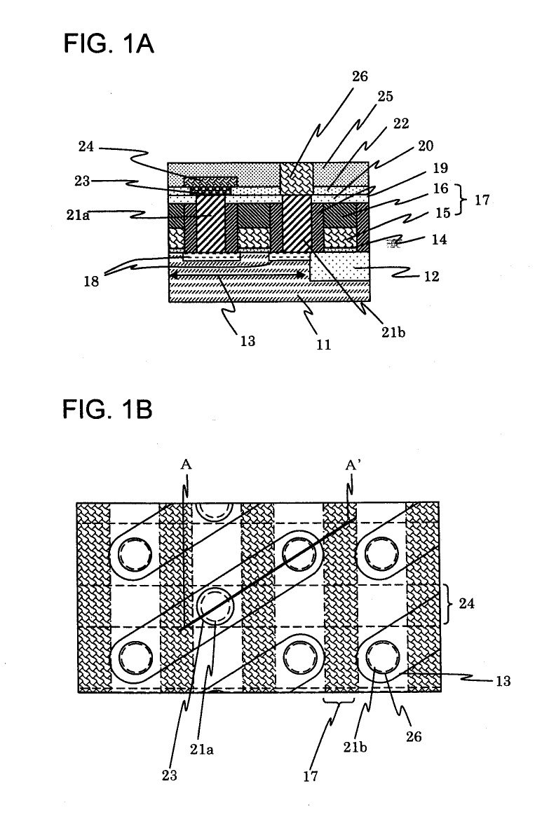

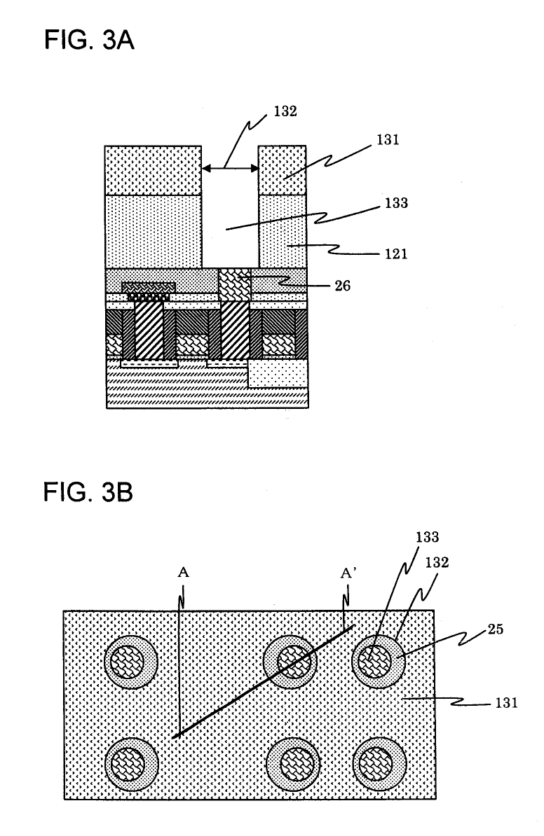

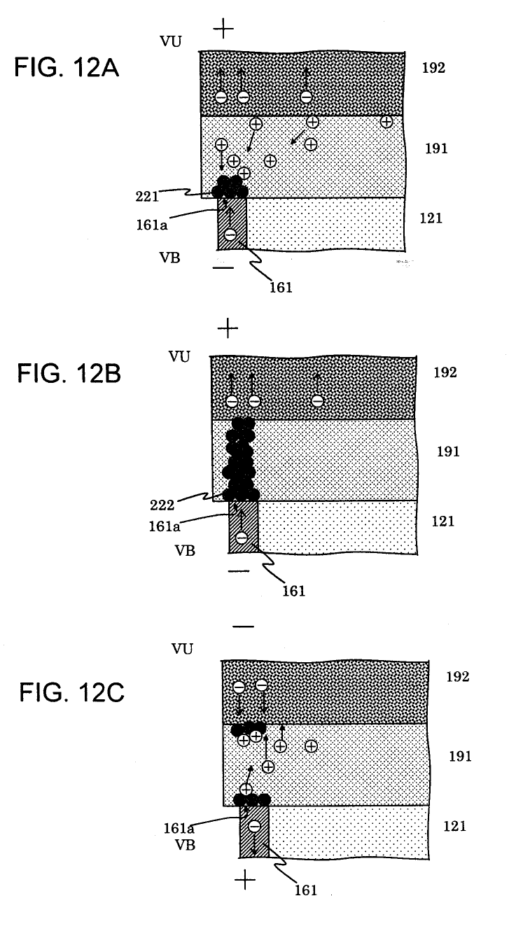

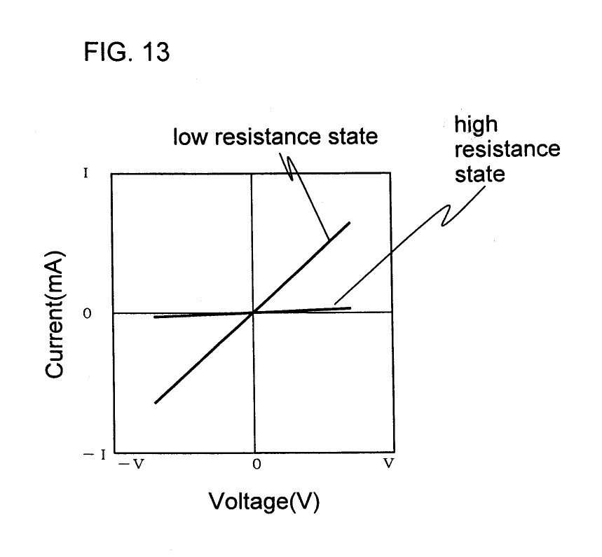

FIGS. 1 to 13 illustrate a first exemplary embodiment of the present invention. FIGS. 3B, 6B, 9B, and 10B are top views of the corresponding structures, and FIG. 1B is a plane view of the corresponding structures with primary layers overlapped. FIGS. 1A to 11A are cross-sectional views corresponding to the structure of FIG. 1B taken along the line A-A′. FIGS. 12A to 12C is a cross-sectional view of an ion conductor memory element for explaining a switching. FIG. 13 illustrates the current-voltage property of the ion conductor memory element.

As FIGS. 1A and 1B illustrate, an element isolation film 12 is formed in a semiconductor substrate 11. The region defined by the element isolation film 12 is a device forming region 13. Gate electrodes 17 are formed by patterning after a gate insulating film 14, a gate conductive film 15, and a gate protection film 16 are formed.

Impurities are implanted into the semiconductor substrate 11 in accordance with an ion implantation process using the gate electrodes 17 as masks, to form source/drain regions 18. Etchback is performed after forming an insulating film on the entire surface of the semiconductor substrate 11, to form sidewalls 19 on the side walls of the gate electrodes 17.

Gate interlayer film 20 is formed so as to fill up regions between the gate electrodes. The gate interlayer film 20 on the source/drain regions 18 is eliminated using photolithography process and etching technology, to form contact holes. A conductive material is filled up in the contact holes to form cell contact plugs 21a, 22b connected to the source/drain regions 18.

The cell contact plug interlayer film 22 is formed on the gate interlayer film 20. Contact holes are formed so as to pass through the cell contact plug interlayer film 22 using photolithography technology and etching technology. A conductive material is filled up in these contact holes, to form source line contact plugs 23 connected to the cell contact plugs 21 a and source lines 24 connected to the source line contact plugs 23.

Source line interlayer film 25 is formed on the source lines 24 and the cell contact plug interlayer film 22. Contact holes are formed so as to pass through the source line interlayer film 25. A conductive material is filled up in these contact holes, to form device contact plugs 26 connected to the cell contact plugs 21b.

FIG. 1B is a plan view of overlapped layers of the device forming region 13, the gate electrodes 17, the cell contact plugs 21a and 21b, the source line contact plugs 23, and the device contact plugs 26. This embodiment has a layout in which selective transistors are formed on the both sides of the source/drain regions 18 so that the selective transistors share the source/drain regions 18 connected to the source lines 24.

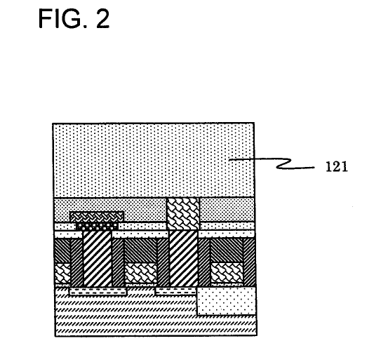

Then, as illustrated in FIG. 2, a device interlayer film 121 is formed. The device interlayer film 121 is a first insulating film. The device interlayer film 121 is an insulating film made of, for example a silicon oxide material, and has 200 nm in thickness.

As illustrated in FIGS. 3A and 3B, a first resist mask 131 is formed so that regions in which device holes are to be formed is opened. Hereinafter, the openings formed in the first resist mask 131 are identified as first resist mask openings 132. In this embodiment, each of the first resist mask openings 132 has a circular pattern having an opening width of 80 nm.

The device interlayer 121 is etched using the first resist mask 131 as a mask, to form element openings 133 in the regions of the first resist mask openings 132, so as to expose the top surface of the device contact plugs 26. The plane shape of the element openings 133 is formed approximately in accordance with the pattern of the first resist mask openings 132.

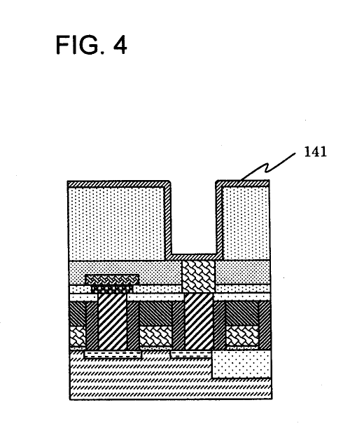

As illustrated in FIG. 4, the first resist mask 131 is removed. A first electrode film 141 is formed with a thickness d to cover the device interlayer film 121 and the bottom and side surfaces of the element openings 133. The material of the first electrode film 141 is selected from the materials that are not easily dissolved by a electrochemical reaction, and that do not easily allow a supply of metal ions to a resistance changing layer, the resistance changing layer comprising a first ion conductor film formed on the first electrode film 141.

In this embodiment, the first electrode film 141 is made of a material of titanium nitride, and is formed by the CVD process with a thickness (d) of 8 nm. The material of the first electrode film 141 is not limited to titanium nitride, but may be at least one film selected from the group consisting of titanium film, tantalum film, tungsten film, molybdenum film, titanium nitride film, tungsten nitride film, tantalum nitride film, platinum film, metal silicide film, and doped silicon film, or may be a laminating film including a plurality of films selected from the group. Furthermore, the first electrode film 141 may be a laminating film including two or more films selected from the group. A method for forming the first electrode film 141 is not limited to the CVD method, but may include the ALD or the sputtering method.

The first electrode film 141 may have a thickness d of not less than about 3 nm as lower limit. The deviation of the thickness falls within about ±10%, and may form in the order of nanometer for a desired dimension. The thickness d of the first electrode film substantially corresponds to the maximum width of a conductive bridge (or conductive crosslink) formed when the device is in operation. The thinner the thickness is, the smaller the maximum width of the formed conductive bridge may be.

The first electrode film 141 may be formed by, for example, the CVD, ALD, or sputter method. The CVD or ALD method, among these methods, is preferable because it is superior to cover the openings with a film, and may easily control the thickness of the first electrode film 141 formed on the side walls of the openings.

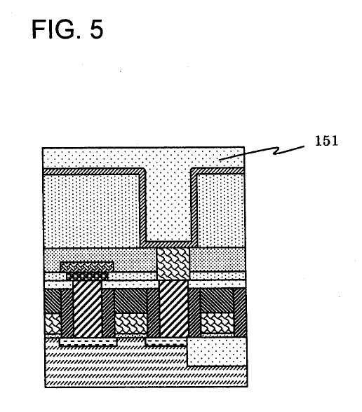

As illustrated in FIG. 5, a buried layer 151 is formed. The buried layer 151 may be made of a material having a higher electronic resistance than the first electrode layer 141. It is because that when a voltage is applied between opposing first and second electrodes with the resistance changing layer interposed therebetween, the electric field applied between an upper portion of the first electrode and the second electrode becomes larger than the electric field applied between the buried layer and the second electrode. The term “electronic resistance” described herein means an electric resistance generated by electronic conduction, and is different from an electric resistance generated by ion conduction of metal ions. Furthermore, an electronic resistance of the buried layer represents the electronic resistance between the top and bottom portions in the relevant height of the buried layer, and an electronic resistance of the first electrode represents the electronic resistance between the top and bottom portions in the relevant height of the side wall of a recessed portion formed as the first electrode.

The buried layer 151 may be made of a material of semiconductor or insulator, such as silicon oxide film, silicon nitride film, metal oxide film, chalcogenide compound film. In this embodiment, silicon oxide film is used. The silicon oxide film has a thickness, with which the element openings 133 are filled up, of 100 nm, for example.

Using the following method, it may be found whether the electronic resistance of the buried layer 151 is larger than the electronic resistance of the first electrode film 141.

According to a manufacturing method of the embodiment, there are prepared three different base substrates including the element openings 133 formed by the step in FIG. 3. Then, the first resist mask 131 is removed as the step in FIG. 4, and three different elements with different structures are thus prepared.

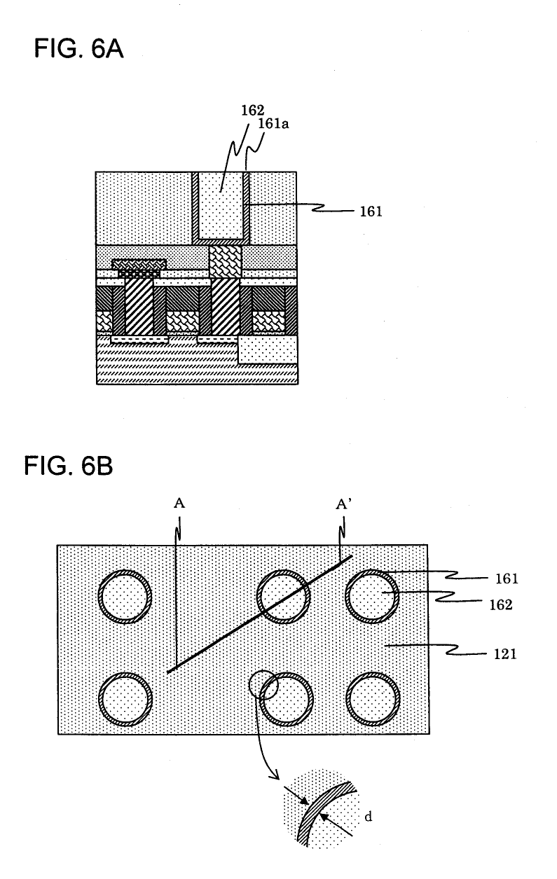

In a first element, the first electrode film 141 and the buried layer 151 are formed in the element openings 133, and then a plug 1 (i.e., a plug formed by the step of FIG. 6) is formed by polishing such as the CMP process. It is then formed an electrode pad connected onto the top surface of the plug 1. Accordingly, a resistance measuring element 1 is formed with the plug 1 sandwiched between the device contact plug 26 and the electrode pad.

In a second element, the first electrode film 141 is formed with a large thickness in the element openings 133, and then a plug 2 is formed by filling up the element openings 133 completely only with the first electrode film 141. It is then formed a resistance measuring element 2 with the plug 2 sandwiched between the device contact plugs 26 and electrode pad.

In a third element, the buried layer 151 is formed with a large thickness in the element openings 133, and then a plug 3 is formed by filling up the element openings 133 completely only with the buried layer 151. It is then formed a resistance measuring element 3 with the plug 3 sandwiched between the device contact plugs 26 and the electrode pad.

A voltage is applied to these three resistance measuring elements, and then each resistance is measured from a current flow. By recognizing whether there is a relationship in resistance, such as the resistance measuring element 3>the resistance measuring element 1, or the resistance measuring element 1>the resistance measuring element 2, it may be confirmed that the electronic resistance of the buried layer 151 is larger than the electronic resistance of the first electrode film 141. The lower portions of the three elements may not necessarily have the device contact plugs 26 formed thereon, but may have substrates or wirings formed thereon.

As illustrated in FIGS. 6A and 6B, the first electrode film 141 is exposed by polishing the buried layer 151 according to the CMP process. Then, the upper surface of the device interlayer 121 is exposed by polishing the first electrode film 141 and the buried layer 151 according to the CMP process, thereby forming a first electrode 161 extending from the bottom surface of the element opening 133 along the side wall of the element opening 133, and also forming a buried layer 162 filled up inside the inner wall of the first electrode. By this step, the upper end 161 a of the first electrode, the upper surface of the buried layer 162, and the upper surface of the device interlayer 121 are formed so as to constitute a same plane. The same plane corresponds to a first plane.

FIG. 6B is a top view of the structure in FIG. 6A. The first electrode 161 is formed along the side wall of the element opening 133, has a circular pattern having an uniform width d, and has a concave shape. The buried layer 162 is formed inside the first electrode 161. In this embodiment, the width d is 8 nm.

The width d of the upper circular portion of the first electrode 161 amounts to the formed thickness of the first electrode film 141. The first electrode film 141 may be formed with a predetermined thickness of not less than about 3 nm, and the first electrode 161 may be formed under control with a predetermined width of not less than about 3 nm. Furthermore, when formed, the deviation of the thickness falls within ±10% on a wafer surface under control in the order of nanometer, and the width d of the first electrode 161 may be within ±10% on its surface under control in the order of nanometer.

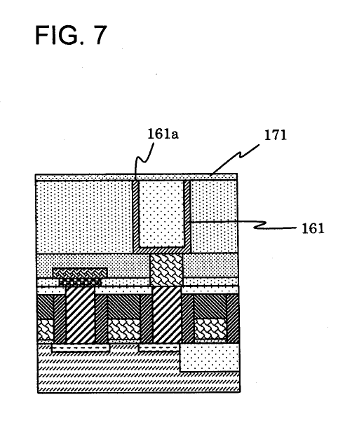

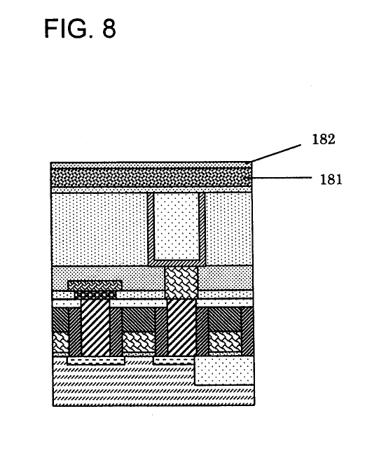

As illustrated in FIG. 7, a resistance changing layer 171 is formed so as to cover the device interlayer film 121, the upper end 161 a of the first electrode, and the buried layer 162. The resistance changing layer 171 may be made of a material having ion conduction for metal ions. The metal ions are supplied from a material of a second electrode layer formed by a step of FIG. 8, as described below, and cations having a small atomic radius and a high mobility are used. In this embodiment, copper, silver or zinc ions are used as metal ions. Preferably, a material having a high electronic resistance is used for the resistance changing layer 171. If an electronic resistance is high, it is possible to make it bigger the difference between a low resistance state and a high resistance state, and thus to secure a wider margin when the difference in resistance is detected with a sense amplifier.

In this embodiment, the resistance changing layer 171 is made of a tantalum oxide film, and has a thickness of 15 nm. The resistance changing layer 171 is formed by the CVD method. The material of the resistance changing layer 171 is not limited to tantalum oxide film, but may be at least one film selected from the group consisting of tantalum oxide film, zirconium oxide film, niobium oxide film, hafnium oxide film, transition metal oxide film such as titanium oxide, aluminum oxide film, metal oxide film such as tungsten oxide film, silicon oxide film, sulfur-containing chalcogenide compound film such as Cu₂S, CuGeS, selenium-containing chalcogenide compound film such as Cu₂Se, CuGeSe, and tellurium-containing chalcogenide compound film such as Cu₂Te, CuGeTe, or may be a laminating film including a plurality of films selected from the group. Among these films, transition metal oxide film is a high permittivity film, and is used as a capacity film of DRAM or a gate insulating film of a transistor. Transition metal oxide film is preferable because it may be easily introduced into a manufacturing line. Silicon oxide film or aluminum oxide film has relatively small ion conductivity, and may thus be become slow in rewrite operation. However, silicon oxide film or aluminum oxide film may be used if there is no problem in a recording speed and a recording voltage. A chalcogenide compound has relatively a small electronic resistance, and may thus be used if there is no problem in the difference in resistance between a high resistance state and a low resistance state when in operation.

This chalcogenide compound may be used if a metal element included in a second electrode later to be formed later is copper. When the second electrode is made of silver, sulfur-containing chalcogenide compound such as Ag₂S, AgGeS, selenium-containing chalcogenide compound such as Ag₂Se, AgGeSe, or tellurium-containing chalcogenide compound such as Ag₂Te, AgGeTe may be used for a chalcogenide compound.

To the extent there is no problem regarding leakage current, it is preferable to make the resistance changing layer 171 thin in thickness, which allows rewrite operation (recording operation or eliminating operation) faster and easier. In this embodiment, the thickness is 15 nm. Since its base is flat, the resistance changing layer 171 may be relatively easily formed. The CVD, ALD, or sputter method may be used to form the resistance changing layer 171.

The resistance changing layer 171 may be formed to include a metallic element (e.g., copper in this embodiment) upon, or right after, forming method. This may increase the concentration of metallic elements in the resistance changing layer 171, and make it easier to form a conductive bridge (or conductive crosslink).

As illustrated in FIG. 8, a second electrode film 181 is formed. The second electrode film 181 functions as a layer for providing metal ions of the metallic elements constituting the electrode into a first ion conductor, i.e., the resistance changing layer 171, by a electrochemical reaction (oxidation reduction reaction). The second electrode film 181 may be made of a material including a metallic element which is able to provide cations having a high mobility of ion conduction and having a small atomic radius. In this embodiment, copper is used as a material for the second electrode film 181. The second electrode film 181 is formed in 50 nm by the sputter method. The metallic element is not limited to copper, and may be silver or zinc.

Among these metallic elements, copper is preferable because copper is a material which has typically been used in semiconductor processes and may be easily introduced into a manufacturing line. The material of the second electrode film 181 may be a material having a high electronic conductivity (i.e., a small electronic resistance) as a chalcogenide compound including copper and silver.

A second electrode mask film 182 is formed on the second electrode film 181. The material of the second electrode mask film 182 is silicon oxide film. The second electrode mask film 182 is used as a hard mask for etching the second electrode film 181.

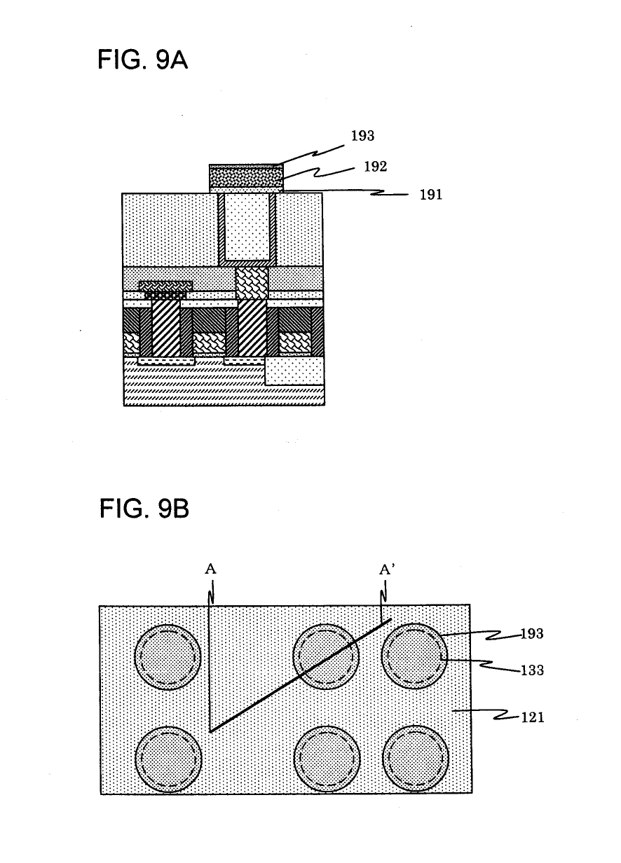

As illustrated in FIGS. 9A and 9B, a resist mask (not shown) having a pattern of the second electrode is formed. Using the resist mask as a mask, a second electrode mask 193 is formed by plasma etching the second electrode mask film 182. Then, the resist mask is removed. Using the second electrode mask 193 as a mask with chlorine gas, a second electrode 192 is pattern-formed by plasma etching the second electrode film 181. Meanwhile, if there is no problem, e.g., in the thermal resistance of the resist, the second electrode film 181 may be plasma-etched, using the resist mask, without forming the second electrode mask film 182. Subsequently, the resistance changing layer 171 is etched to form a resistance changing layer 191, and the upper surface of the device interlayer film 121 is exposed.

FIG. 9B is a top view of the structure formed after patterning the second electrode 192, with the outline of the element openings 133 overlapped thereon. The second electrode 192 is formed so as to cover the element opening 133. The second electrode 192 may be not formed so as to cover the element opening 133, and may be formed so as to cover at least parts of the first electrode 161 and the buried layer 162

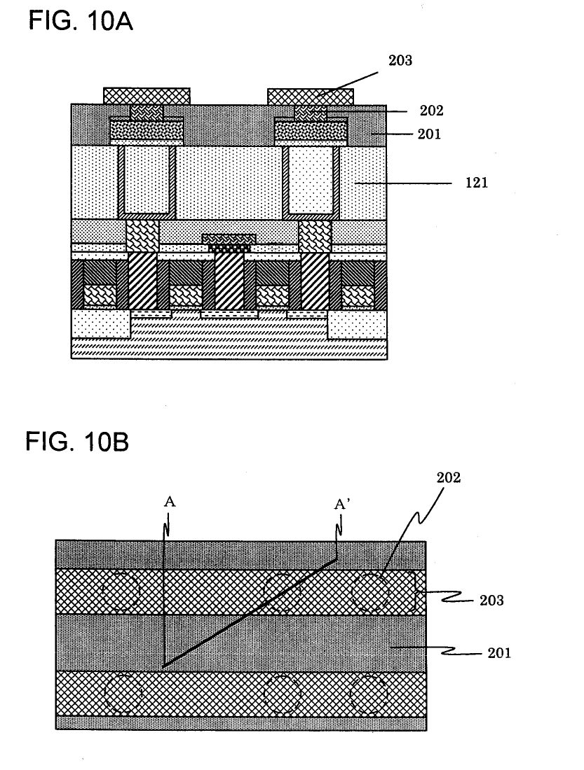

As illustrated in FIGS. 10A and 10B, a second electrode interlayer film 201 is formed in order to cover the second electrode mask 193 and the device interlayer film 121. Using photolithography technology, contact holes are formed so that contact holes pass through the second electrode interlayer film 201 and the second electrode mask layers 193, to expose a portion of the second electrodes 192. The contact holes are filled up with conductive material, to form bit line contact plugs 202 which are connected to the second electrode 192. Bit lines 203, which are connected to the bit line contact plugs 202, are formed on the second electrode interlayer film 201.

FIG. 10B is a top view of the structure formed after patterning the bit lines 203. The bit lines 203 are formed so as to extend perpendicularly with respect to the direction along which the gate electrodes 17 extend. The bit lines 203 are formed in order to connect the second electrodes 192 of a plurality of ion conductor memory elements.

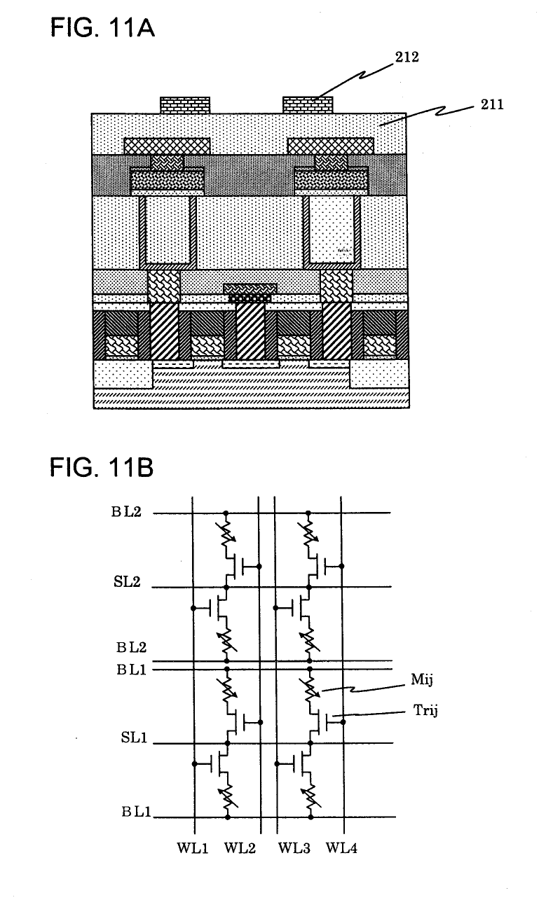

As illustrated in FIGS. 11A and 11B, a bit line interlayer film 211 is formed in order to cover the bit lines 203 and the second electrode interlayer film 201. A peripheral contact plug (not shown) connected to the bit lines is formed. Upper wirings 212 connected to the peripheral contact plug are formed. After that, an interlayer film, a through-hole, a wiring, and a passivation film are formed as necessary, and then a semiconductor device is achieved according to the present invention.

FIG. 11B is a schematic view of a memory cell array of an ion conductor memory element according to the embodiment. A word line WLi (herein, i is an integer from 1 to 4), a bit line BLj (herein, j is 1 or 2), and a source line SLj (herein, j is 1 or 2) are arranged. This embodiment includes both of adjacent BLj and BLj′. A selective transistor Trij and a memory element Mij are arranged at a point at which a word line WLi and a bit line BLj intersect. FIG. 11B shows eight selective transistors, four word lines (WL1, WL2, WL3, WL4), four bit lines (BL1, BL2), and two source lines (SL1, SL2), and shows regions at which eight ion conductor memory elements are arranged. A memory cell Mij is selected by activating WLi and BLj. Here, a word line WLij is a gate electrode 17.

FIGS. 12A to 12C illustrate a rewrite operation of an ion conductor memory element according to the embodiment, enlarging a portion adjacent to the resistance changing layer 191. A voltage of the first electrode is indicated as VB, and a voltage of the second electrode is indicated as VU. In FIG. 12, “−” represents an electron, “+” is a Cu²⁺ ion, and “” indicates deposited copper. FIG. 12A illustrates an initial state, in which data is in a high resistance state (“0” data).

With respect to FIGS. 12A and 12B, a recording operation for switching an ion conductor memory element into a low resistance state will be hereinafter described. When a lower voltage is applied to the first electrode 161 than to the second electrode 192, copper at an interface portion of the second electrode 192 is oxidized to become copper ions (Cu²⁺), and begins dissolving in the resistance changing layer 191. Because a higher electric field is applied to a region between the upper end 161a of the first electrode and the second electrode 192 with the resistance changing layer 191 interposed therebetween, than to other regions, the copper ions moves to that region by attraction.

The copper ions that have reached the surface of the upper end 161a of the first electrode receives electrons and reduced, and then are deposited as copper. The deposited product of copper is identified herein as a “deposited product 221.” (FIG. 12A)

As copper ions are supplied to the resistance changing layer 191 from the second electron 192, the copper ions are deposited on the upper end 161a of the first electrode, and finally the deposited product 221 reaches and bridges the surface of the second electrode 192, thereby forming a conductive bridge (or conductive crosslink) 222 (FIG. 12B). The conductive bridge 222 is made of a metallic element of copper, and acts as a copper wiring having a very narrow width. The resistance between the first and second electrodes becomes very low, which is identified as a low resistance state (“1” data). Accordingly, a record operation is carried out.

The width of the conductive bridge 222 formed is substantially equal to, or smaller than, the width d of the upper end 161 a of the first electrode. In this embodiment, d is 8 nm. The width d of the first electrode 161 may be formed in the order of nanometer, and thus the maximum width of the conductive bridge 222 may be limited to approximately equal to, or smaller than, the width d. As such, the maximum width of the conductive bridge 222 may be limited, and it is possible to prevent a formation of a conductive bridge 222 having a large width. Furthermore, the maximum width may be controlled by the formed width of the first electrode 141, and may be controlled, from about 3 nm as minimum width, in the order of nanometer.

In the embodiment, since the first electrode 161, which acts as a deposition electrode, has a small region of its portion brought into contact with the resistance changing layer, the deposition of copper occurs intensively, thereby making an amount of copper ions necessary for formation of a conductive bridge 222 to be small. Accordingly, the oxidized amount on the surface of the second electrode 192 decreases, and thus a record operation may perform in a shorter period of time.

With respect to FIG. 12C, an elimination operation of an ion conductor memory element will be described hereinafter. In a low resistance state, a polarity opposite to the one in a record operation is applied. In other words, a higher voltage is applied to the first electrode 161 than to the second electrode 192. Copper, which constitutes the conductive bridge 222, is oxidized from the side adjacent to the upper end of the first electrode 161, thereby becoming copper ions and beginning dissolving in the resistance changing layer 191. The copper ions dissolved in the resistance changing layer 191 are deposited and recovered by receiving electrons on the surface of the second electrode 192. As the dissolution progresses, the conductive bridge 222 is cut, thereby becoming the higher resistance state. This state is indicated as a high resistance state (“0” data), and an elimination operation is carried out accordingly (FIG. 12C). Also, the first electrode 161 is made of a material which is hard to dissolve in the resistance changing layer 191, and therefore a formation of a conductive bridge is prohibited due to a supply of metal ions from the first electrode 161 to the resistance changing layer 191.

Since the conductive bridge 222 is formed in a width not larger than the width d, the conductive bridge 222, thereby cutting the conductive bridge having a length of d in width continues to dissolve. Therefore, an elimination time may be reduced within a predetermined time. It is possible to prohibit a time necessary for elimination operation, which is to be taken to dissolve a thick conductive bridge, as in a related art.

As described above, a semiconductor device according to the embodiment may perform a switching by means of a reversible change between an electric connection state and an electric isolation state of a conductive bridge, on the basis of a polarity of voltage between a first electrode and a second electrode. As a result, an ion conductor memory device according to the embodiment includes a structure of a first circular electrode, a second plane electrode, and a resistance changing layer interposed between the first and second electrodes. Since the resistance changing layer and the first electrode are in circular line contact, the region at which a conductive bridge may be formed within a small circular width, i.e., a width between the inner and outer diameters of a ring).

As a result, the maximum width of a conductive bridge formed may be limited to not more than the circular width, and the maximum variation in an elimination time may be reduced upon elimination operation of the conductive bridge. Therefore, a rewrite operation time of a memory element may be reduced.

As the formed thickness of the first electrode may be controlled upon forming, the circular width of the first electrode may be controlled in the order of nanometer. Accordingly, the maximum width of the conductive bridge may be controlled in the order of nanometer when formed. The first electrode having small circular width is formed to reduce a maximum width of the conductive bridge, thereby reducing the maximum time of elimination operation may be reduced and shortening a time taken to rewrite operation.

Also, since the thickness of the first electrode is controllable within ±10% on the wafer surface, the circular width may be formed so that the variation of the circular width is controlled to be smaller. As a result, the variation in a time for elimination operation may be shortened as well on the wafer surface. Furthermore, this prevents a thick conductive bridge 222 from being accidentally formed based on a core such as a fault formed as the first electrode, and thereby effectively enhancing the yield.

The width d of the first electrode may be from 3 nm to 15 nm. A thicker d makes a time for elimination operation longer due to a thick conductive bridge, and a thinner d makes the resistance of the conductive bridge high and thus reduces the difference in resistance between a low resistance state and a high resistance state. The size of d may be determined in consideration of an effect on a rewrite operation or a record operation as the parasitic resistance of the first electrode gets higher.

In the embodiment, since each of a plurality of cells may control each elimination time within a regular time, the simultaneous elimination operations with respect to the plurality of cells may be carried out within the regular time. In FIG. 11, by activating WLi and n bit lines BLj (herein, j is an integer from 1 to n), elimination operations with respect to the cells on WLi may be carried out at the same time. In this way, elimination operations may be achieved simultaneously for a plurality of cells, thereby allowing a quicker rewriting operation.

Reading is performed by applying a smaller voltage than the one utilized for the elimination or recording operation, and then by detecting a current. The very small voltage is applied so that it does not have adverse affect on a conductive bridge.

Since the low and high resistance states of an ion conductor memory reflect whether a metallic wiring is open or broken, a large difference in resistance, e.g., not less than an order of 1, may be secured. The very higher difference in resistance may be maintained, compared to memory device such as MRAM (Magnetic Random Access Memory), and may allow a large margin in read operation.

FIG. 13 shows a voltage-current property when a voltage in the second electrode is swept. The horizontal axis represents a voltage of the second electrode with respect to the first electrode, and the vertical axis represents a current from the first electrode to the second electrode. The line going up adjacent to the horizontal axis with a gentle slope corresponds to a high resistance state (“0” data). The line, along which a current increases in accordance with a current-voltage property of the line having a relatively steep slope to the upper right direction, corresponds to a low resistance state (“1” data). The difference in resistance between the high and low resistance states may be guaranteed in the order of not less than 1. Data may be determined based on this difference in resistance by means of a current detection sense amplifier.

### Second Exemplary Embodiment

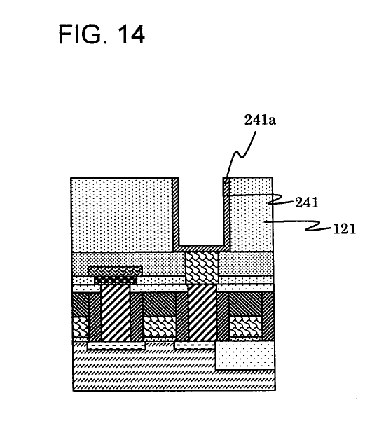

The second exemplary embodiment relates to a method for manufacturing an ion conductor memory element with a different method for forming a first electrode and a buried layer from the first exemplary embodiment. FIGS. 14 to 16 illustrate the second exemplary embodiment, and a cross-sectional view of the structure corresponding to the structure of FIG. 1B taken along the line A-A′. Hereinafter, a step identical to that in the first exemplary embodiment would be omitted, or briefly described. Also, a step in third, fourth, and fifth exemplary embodiments, which is identical to that in the first exemplary embodiment, would be omitted, or briefly described.

The steps up to the one of FIG. 4 in the first exemplary embodiment, which is to form a first electrode, are identically carried out according to this embodiment. After the step of FIG. 4, the first electrode film 141 on the device interlayer film 121 is removed by the CMP method, and the first electrode film 141 is left on the inner side surface and the inner bottom surface of the element opening 133, to form a first electrode 241 having a concave shape (FIG. 14).

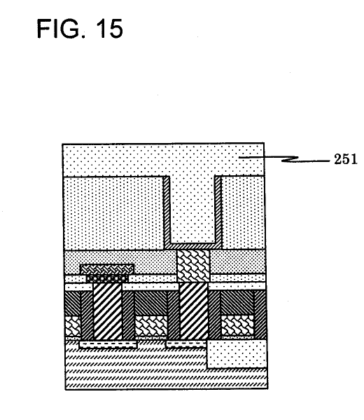

As illustrated in FIG. 15, a buried layer 251 is formed according to the same method as that in FIG. 5 of the first exemplary embodiment.

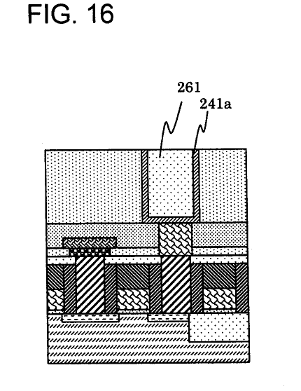

As illustrated in FIG. 16, the buried layer 251 is removed by polishing step in the CMP method, and the first electrode 241 is filled up with the buried layer 251 to form a buried layer 261. At this point, the upper end 241a of the first electrode is exposed. Also, the CMP method may be replaced by etch-back process. Then, the same process as in FIG. 7 of the first exemplary embodiment is performed.

In the step of FIG. 6 of the first exemplary embodiment, which is to form the first electrode, the buried layer 151 is polished in a polishing step of the CMP method, and then the first electrode layer 141 is removed by polishing. In this step, under a condition where a polishing speed of the buried layer 151 is slow, there has been a problem in which the buried layer 151 protrudes vertically with respect to the substrate and the first electrode film 141 therearound is not fully cut out and remains. Therefore, it has been required to perform a polishing under a condition where a polishing speed of the first electrode film 141 is substantially the same as that of the buried layer 151.

In contrast, in the present embodiment, the first electrode layer and the buried layer 251 are independently removed by polishing, and thus a polishing may be performed without such a limitation on a polishing condition.

As a result, the problem of the residual of the first electrode layer may be prevented from occurring.

### Third Exemplary Embodiment

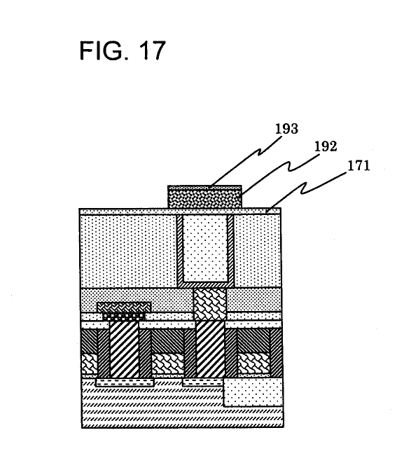

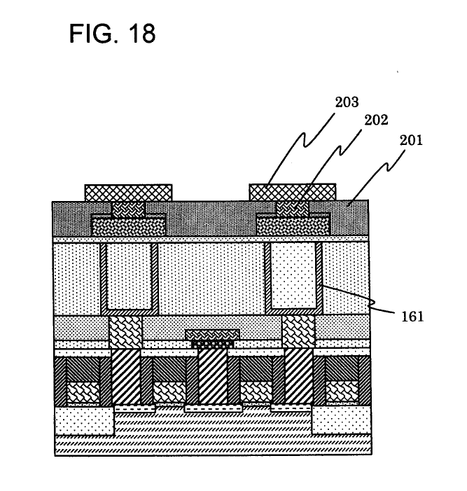

A third exemplary embodiment describes a method for manufacturing an ion conductor memory element including a different structure of the resistance changing layer 191 from that in the first exemplary embodiment. FIGS. 17 to 18 illustrate the third exemplary embodiment, and are sectional views corresponding to a sectional view of the structure of FIG. 1B taken along the line A-A′.

The steps up to one of FIG. 8 that is to form the second electrode mask film 182 according to the first exemplary embodiment are identically carried out in this embodiment as well. Likely to the step of FIG. 9 in the first exemplary embodiment, a resist mask (not shown) having a pattern of a second electrode is formed. The second electrode mask film 182 is etched using that resist mask, and to form the second electrode mask 193. After the resist mask is removed, the second electrode film 181 is etched, using the second electrode mask 193 as a mask, to form the second electrode 192, and to expose the resistance changing layer 171 (FIG. 17).

As illustrated in FIG. 18, in the third exemplary embodiment, the second electrode interlayer film 201 is formed as in FIG. 10 of the first exemplary embodiment, while the resistance changing layer 171 is left without patterning. Then, the same steps as in first exemplary embodiment are carried out.

In the third exemplary embodiment, an etching for patterning of the resistance changing layer 171 may be omitted, and the etching step may be simplified. In this embodiment, the resistance changing layers are connected between the adjacent cells because the resistance changing layer 171 is not patterned. Therefore, when a rewrite is performed on a desired cell, a voltage is applied between the second electrode and the first electrode of the adjacent cell via the first ion conductor, and thus a problem may occur in which a conductive bridge (or conductive crosslink) is formed on the adjacent cell, or the conductive bridge on the adjacent cell dissolves, etc. This embodiment may be applied to the memory device where the ion conductor between these adjacent cells has a sufficiently high resistance, and no interference occurs.

### Fourth Exemplary Embodiment

In the first to third exemplary embodiments, a second electrode is made of a material capable of providing the resistance changing layer, i.e., the first ion conductor with metal ions of a metallic element constituting the electrode by an electrochemical reaction (oxidation reduction reaction). The first electrode is made of a material which does not easily dissolve by an electrochemical reaction. In contrast, in the fourth exemplary embodiment, the first electrode is made of a material capable of providing the resistance changing layer, i.e., the first ion conductor with metal ions of a metallic element constituting the electrode by an electrochemical reaction (oxidation reduction reaction). The second electrode is made of a material which does not easily dissolve by an electrochemical reaction. The fourth exemplary embodiment differs from the first to third exemplary embodiments as above.

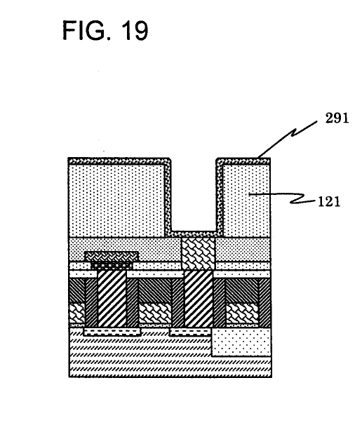

FIGS. 19 to 21 are views for describing the fourth exemplary embodiment, and cross-sectional views corresponding to the cross-sectional view of the structure of FIG. 1B taken along the line A-A′.

In this embodiment, the same steps as in the first exemplary embodiment are performed up to the step of FIG. 3 in the first exemplary embodiment. After the first resist mask is removed, the first electrode film 291 is formed so as to cover the bottom and side of the inner wall of the element opening 133 and also to cover the device interlayer film 121. The first electrode film 291 is made of a material capable of providing the resistance changing layer 171, i.e., the first ion conductor with metal ions of a metallic element constituting the electrode by a electrochemical reaction (oxidation reduction reaction), and the material is copper film. The CVD method, which has a high coverage, is used to form the first electrode film 291. Its thickness is 8 nm (FIG. 19).

The material of the first electrode film 291 may be a material having a lower electronic resistance than of the buried layer. Other these material such as silver or zinc may be used instead of copper. Among other things, copper is preferable in that it may be easily introduced into a manufacturing line.

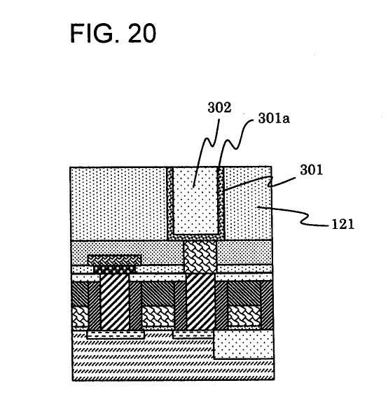

As illustrated in FIG. 20, the buried layer 151 is formed according to the step of FIG. 5 of the first exemplary embodiment. The first electrode layer 291 is exposed by polish-removing the buried layer 151 by the CMP method. Then, the upper surface of the device interlayer film 121 is exposed by polish-removing the first electrode film 291 and the buried layer 151 by the CMP method. As a result, the first electrode 301 is formed over from the bottom surface to the side surface of the inner wall of the element opening 133, and the buried layer 302 is formed being filled in the inner wall of the first electrode 301. The upper end 341a of the first electrode 301a and the upper surface of the buried layer 302 are flush with the upper surface of the device interlayer film 121.

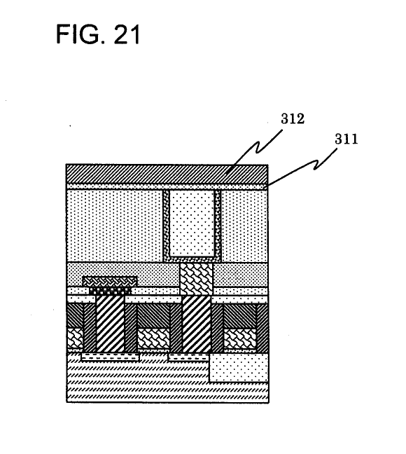

As illustrated in FIG. 21, a resistance changing layer 311 is formed according to the same step as in FIG. 7 of the first exemplary embodiment. A second electrode film 312 is formed on the resistance changing layer 311. The second electrode film 312 is made of a material which is not easily dissolved by an electrochemical reaction. In this embodiment, the second electrode film 312 is formed using a titanium nitride film, and has a thickness of 50 nm formed by sputter method. The material of the second electrode film 312 is not limited to a titanium nitride film, but may be at least one film selected from the group consisting of titanium film, tantalum film, tungsten film, molybdenum film, titanium nitride film, tungsten nitride film, tantalum nitride film, platinum film, metal silicide film, and doped silicon film, or may be a laminating film including a plurality of films selected from the group.

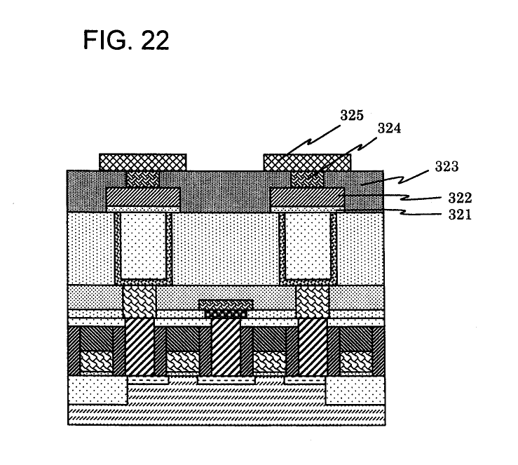

As illustrated in FIG. 22, a resist mask (not shown) having a pattern of the second electrode is formed. Using this resist mask as a mask, the second electrode film 312 and the resistance changing layer 311 are plasma-etched in this order, to form a second electrode 322 and a resistance changing layer 321. After the resist mask is removed, a second electrode interlayer film 323, a bit line contact plug 324, and a bit line 325 are formed, according to the step of FIG. 10 of the first exemplary embodiment. Then, the same step as FIG. 11 of the first exemplary embodiment is performed.

In the fourth exemplary embodiment, the polarity of voltage applied to the first and second electrodes upon a write and elimination of re-write operation is reversed compared to the first to third exemplary embodiments. In the first to third exemplary embodiments, the second electrode is made of copper, and is formed by patterning by means of plasma etching, which makes the process relatively difficult, and thus a hard mask is required to be used. In contrast, this embodiment preferably allows the first electrode to be made of copper, and formed by the CMP method and without a process including plasma etching.

### Fifth Exemplary Embodiment

A fifth exemplary embodiment relates to a method for manufacturing an ion conductor memory element supplying metal ions for ion conduction from a buried layer. First and second electrodes are made of a material which is not easily dissolved by an electrochemical reaction.

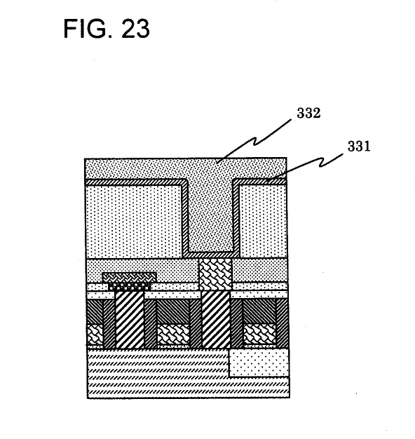

FIGS. 23 to 25 illustrate the fifth exemplary embodiment, and cross-sectional views corresponding to cross-sectional view of the structure of FIG. 1B taken along the line A-A′.

As illustrated in FIG. 23, until the first electrode film 331 is formed in accordance to the step of FIG. 4 of the first exemplary embodiment, the same steps as in the first exemplary embodiment are performed. The first electrode film 331 is made of a material which is not easily dissolved by an electrochemical reaction. In this embodiment, a titanium nitride film is used for the first electrode film 331. The material of the first electrode film 331 is not limited to a titanium nitride film, but may be at least one film selected from the group consisting of titanium film, tantalum film, tungsten film, molybdenum film, titanium nitride film, tungsten nitride film, tantalum nitride film, platinum film, metal silicide film, and doped silicon film, or may be a laminating film including a plurality of films selected from the group. The first electrode film 331 has a thickness of 8 nm.

A buried layer 332 is formed so as to fill up the element opening 133. The buried layer 322 is made of a material having ion conductivity for metal ions and is formed so as to include a metallic element which performs ion conduction into the second ion conductor. The metal ions may be cations having high mobility, and is copper ions in this embodiment. The metal ions may also be silver ions or zinc ions. The buried layer 332 is made of a material having a higher electronic resistance than that of the first electrode film 331.

In this embodiment, the buried layer 332 is made of Cu₂S. The buried layer 332 is formed by sputter method. The material of the buried layer 332 is not limited to the aforementioned, but may be at least one film selected from the group consisting of tantalum oxide film, zirconium oxide film, niobium oxide film, hafnium oxide film, transition metal oxide film of titanium oxide, aluminum oxide film, metal oxide film of tungsten oxide film, silicon oxide film, sulfur-containing chalcogenide compound film, selenium-containing chalcogenide compound film, and tellurium-containing chalcogenide compound film, each including the metallic elements, or may be a laminating film including a plurality of films selected from the group. The chalcogenide compound may be sulfur-containing chalcogenide compound of Cu₂S, CuGeS, selenium-containing chalcogenide compound of Cu₂Se, CuGeSe, and tellurium-containing chalcogenide compound of Cu₂Te, CuGeTe, when the metallic element is copper. When silver is used as a metallic element, the chalcogenide compound may be tellurium-containing chalcogenide compound of Ag₂Te, AgGeTe.

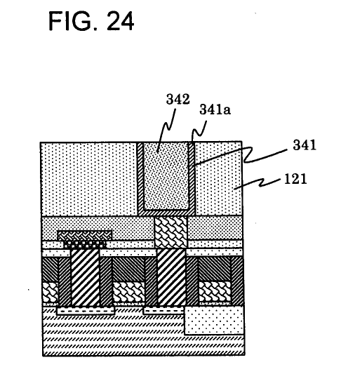

As illustrated in FIG. 24, the buried layer 332 and the first electrode layer 331 are polished and removed by the CMP method, to expose the device interlayer film 121. Furthermore, the first electrode 341 is formed so as to cover the bottom and side surfaces of the inner wall of the element opening 133, and a buried layer 342 is formed in a first electrode 341 of the element opening 133.

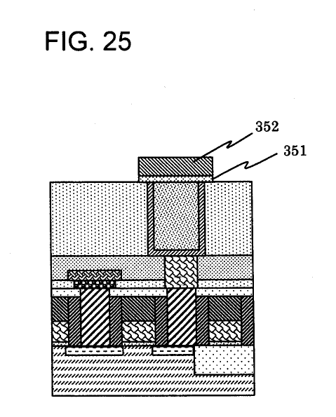

As illustrated in FIG. 25, a resistance changing layer is formed according to the same step as in FIG. 7 of the first exemplary embodiment. When chalcogenide compound is used as the material of the resistance changing layer, if the metallic element included in the buried layer 342 is copper, sulfur-containing chalcogenide compound of Cu₂S, CuGeS, or selenium-containing chalcogenide compound of Cu₂Se, CuGeSe may be used. If the metallic element is silver, sulfur-containing chalcogenide compound of Ag₂S, AgGeS, selenium-containing chalcogenide compound of Ag₂Se, AgGeSe, or tellurium-containing chalcogenide compound of Ag₂Te, AgGeTe may be used.

A second electrode film is formed on the resistance changing layer. The second electrode film is made of a material which is not easily dissolved by an electrochemical reaction in the resistance changing layer of a first ion conductor film. In this embodiment, the second electrode film is made of a titanium nitride film. The material of the second electrode film is not limited to titanium nitride, but may be at least one film selected from the group consisting of titanium film, tantalum film, tungsten film, molybdenum film, titanium nitride film, tungsten nitride film, tantalum nitride film, platinum film, metal silicide film, and doped silicon film, or may be a laminating film including a plurality of films selected from the group. The second electrode film is formed so as to have a thickness of 50 nm by sputter method.

According to the same step as in FIG. 9 of the first exemplary embodiment, a resist mask (not shown) is formed so as to have a pattern of a second electrode, and the second electrode film and the resistance changing layer are etched using the mask, to form the second electrode 352 and a resistance changing layer 351.

Then, the same steps are performed as those beginning from that in FIG. 10 of the first exemplary embodiment.

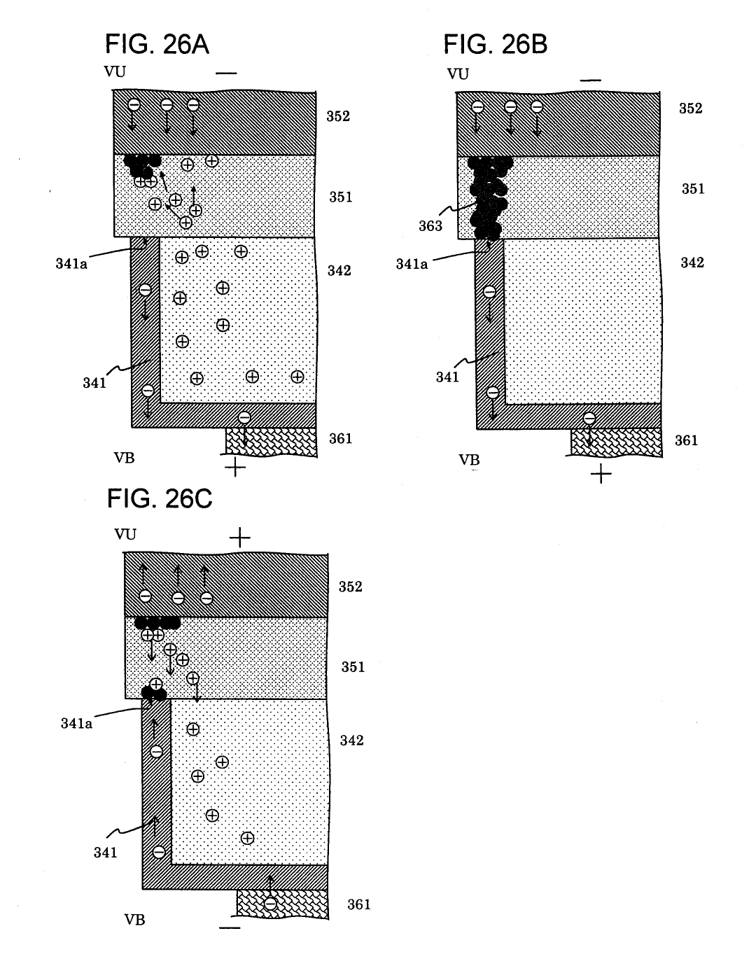

FIGS. 26A to 26C illustrate a rewrite operation of an ion conductor memory element according to the embodiment. FIG. 26 is an enlarged view of the proximate of the resistance changing layer 351. The voltage applied to the first and second electrodes is reversed compared to the first exemplary embodiment, i.e., the same polarity as in the fourth exemplary embodiment. FIG. 26 depicts that a device contact plug 361 is connected below the first electrode 314, and a bit line contact plug (not shown) is connected on the second electrode 352. In FIG. 26, “−” indicates an electron, “+” is Cu²⁺, and a gray “” is a deposited copper. In an initial state, the resistance changing layer 351 is in a high resistance state (“0” data) (FIG. 26A).

A lower voltage is applied to the second electrode 352 than to the first electrode 341. Copper in the buried layer 342 adjacent to the first electrode 341 is oxidized by transferring electrons to the first electrode 341, thereby becoming copper ions (Cu²⁺). The region interposed between the upper end (341a) of the first electrode and the second electrode 352 intensively attracts copper ions due to a high application of electric field thereof.

Copper ions are reduced into cupper by receiving electrons from the electrode on the surface of the second electrode 352, and begin to be deposited as a metal on the second electrode 352. The deposition occurs in advance on the region interposed between the upper end (341a) of the first electrode and the second electrode 352, to which an electric field is applied intensively. The deposition of copper proceeds, and a conductive bridge (or conductive crosslink) 363 is formed so as to extend from the second electrode 352 to the upper end 341a of the first electrode, thereby becoming a low resistance state. A low resistance state (“1” data) is ready, and a write operation is performed (FIG. 26B).

Since the conductive bridge 363 is formed selectively between the upper end (341a) of the first electrode and the second electrode (352), the width of the conductive bridge 363 is formed within the width of the first electrode 341. According to the first exemplary embodiment, the width of the first electrode 341 may be controlled into the formed thickness of the first electrode film, and it is possible to control the maximum width of the conductive bridge 363.

In this state, a higher voltage is applied to the second electrode 352 than to the first electrode 341, with the polarity reversed between the first and second electrodes. Copper constituting the conductive bridge 363 adjacent to the second electrode 341 is oxidized, and begin to dissolve in the resistance changing layer 351 as copper ions. The first and second electrodes 341 and 352 are made of a material which is not easily dissolved in the resistance changing layer 351, and copper or other metals is not supplied into the resistance changing layer 351 from the first and second electrodes 341 and 352. Ion coppers dissolved in the resistance changing layer 351 diffuse into the buried layer 342, and are reduced into metals in the buried layer 342 by the first electrode 341. As the oxidization of the conductive bridge proceeds, it is cut finally, thereby becoming a high resistance state (“0” data), and an elimination operation is carried out (FIG. 26C).

In this embodiment, according to the first to fourth exemplary embodiments, the conductive bridge may be formed between the first electrode including a circular shape of its upper end and the second electrode, and the maximum width of the conductive bridge may be controlled within the width of the circular portion of the first electrode. In the first to fourth exemplary embodiments, the supply of a metallic element for ion conduction is rendered by dissolution of a metal from the first or second electrode. In this embodiment, however, the first and second electrodes are made of a material which does not dissolve in the resistance changing layer, and metal ions for ion conduction are supplied from the buried layer. Since a metal accumulates in the buried layer, and metal ions may accumulate in a high concentration, thereby allowing to a rapid rewrite operation. Furthermore, since no supply of a meal is carried out from the first or second electrode, there exists no problem of deformation of the electrode by a rewrite operation, thereby improving reliability.

### Modifications of First to Fifth Exemplary Embodiments

The first through fifth exemplary embodiments disclose that the first electrode has a circular shape, which is provided on the side and bottom surfaces of the inner wall of the cylindrical element opening. In this case, the upper end of the first electrode, which is in contact with the resistance changing layer, is a circumferential portion. However, in the present invention, the shape of the first electrode is not limited to be circular, and may be a square pillar shape, or an indeterminate shape provided on the side and bottom surfaces of the inner wall of the cylindrical element opening. Even in this case, the upper end of the first electrode may be controlled so as to have a certain width of not less than about 3 nm, within ± about 10% on the surface in the order of nanometer, as the circular first electrode.

It is apparent that the present invention is not limited to the above embodiments, but may be modified and changed without departing from the scope and spirit of the invention.

In addition, while not specifically claimed in the claim section, the applications reserve the right to include in the claim section at any appropriate time the following method:
1. A method for manufacturing a semiconductor device, comprising:

forming an opening extending from a surface of a first insulating film in a thickness direction thereof;

forming a first electrode in the opening so as to cover side and bottom surfaces of an inner wall of the opening and so as to include a recessed portion;

forming a buried layer in the recessed portion of the first electrode, the buried layer having a higher electronic resistance than an electronic resistance of the first electrode;

forming a resistance changing layer containing a first ion conductor on an upper end of the first electrode and the buried layer; and

forming a second electrode on the resistance changing layer so as to interpose the resistance changing layer between the upper end of the first electrode and the buried layer, and the second electrode.
2. The method according to the above 1,

wherein any one of the first and second electrodes includes a metallic element capable of dissolving into the first ion conductor by an electrochemical reaction.
3. The method according to the above 2,

wherein the metallic element is at least one element selected from the group consisting of copper, silver and zinc.
4. The method according to the above 1,

wherein one of the first and second electrodes includes a metallic element capable of dissolving into the first ion conductor by an electrochemical reaction, and

the other of the first and second electrodes is made of at least one film selected from the group consisting of titanium film, tantalum film, tungsten film, molybdenum film, titanium nitride film, tungsten nitride film, tantalum nitride film, platinum film, metal silicide film, and doped silicon film.
5. The method according to the above 4,

wherein the first ion conductor is made of at least one film selected from the group consisting of tantalum oxide film, zirconium oxide film, niobium oxide film, hafnium oxide film, titanium oxide film, aluminum oxide film, tungsten oxide film, silicon oxide film, sulfur-containing chalcogenide compound film, selenium-containing chalcogenide compound film, and tellurium-containing chalcogenide compound film.
6. The method according to the above 1,

wherein the buried layer includes a second ion conductor, and

the second ion conductor includes a metallic element capable of dissolving into the first ion conductor by an electrochemical reaction.
7. The method according to the above 6,

wherein the metallic element is at least one element selected from the group consisting of copper, silver and zinc.
8. The method according to the above 6,

wherein the first and second electrodes are independently made of at least one film selected from the group consisting of titanium film, tantalum film, tungsten film, molybdenum film, titanium nitride film, tungsten nitride film, tantalum nitride film, platinum film, metal silicide film, and doped silicon film.
9. The method according to the above 6,

wherein the first and second ion conductors are independently made of at least one film selected from the group consisting of tantalum oxide film, zirconium oxide film, niobium oxide film, hafnium oxide film, titanium oxide, aluminum oxide film, tungsten oxide film, silicon oxide film, sulfur-containing chalcogenide compound film, selenium-containing chalcogenide compound film, and tellurium-containing chalcogenide compound film.

1. A semiconductor device including a semiconductor element, comprising:
a first insulating film including an opening which extends inside from a first surface in a thickness direction thereof;
a resistance changing layer formed on the first surface of the first insulating film and including a first ion conductor;
a first electrode formed within the opening so as to cover side and bottom surfaces of an inner wall of the opening and so as to include a recessed portion, the first electrode being in contact with the resistance changing layer via an upper end thereof;
a buried layer filling up the recessed portion of the first electrode and having a higher electronic resistance than the first electrode; and
a second electrode formed on the resistance changing layer so as to interpose the resistance changing layer between the second electrode, and the upper end of the first electrode and the buried layer,
wherein the semiconductor element reversibly forms a conductive bridge in the resistance changing layer between the upper end of the first electrode and the second electrode so as to change an electronic resistance between the first and second electrodes.

2. The semiconductor device according to claim 1,
wherein any one of the first and second electrodes contains a metallic element capable of dissolving into the first ion conductor by an electrochemical reaction, and
the conductive bridge is made of the metallic element.

3. The semiconductor device according to claim 2,
wherein the metallic element is at least one element selected from the group consisting of copper, silver and zinc.

4. The semiconductor device according to claim 1,
wherein one of the first and second electrodes contains a metallic element capable of dissolving into the first ion conductor by an electrochemical reaction, and
the other of the first and second electrodes is made of at least one film selected from the group consisting of titanium film, tantalum film, tungsten film, molybdenum film, titanium nitride film, tungsten nitride film, tantalum nitride film, platinum film, metal silicide film, and doped silicon film.

5. The semiconductor device according to claim 4,
wherein the first ion conductor is made of at least one film selected from the group consisting of tantalum oxide film, zirconium oxide film, niobium oxide film, hafnium oxide film, titanium oxide film, aluminum oxide film, tungsten oxide film, silicon oxide film, sulfur-containing chalcogenide compound film, selenium-containing chalcogenide compound film, and tellurium-containing chalcogenide compound film.

6. The semiconductor device according to claim 2,
wherein the metallic element and the first ion conductor meet the following condition (1) or (2):
(1) the metallic element is copper, and the first ion conductor contains at least one material selected from the group consisting of Cu₂S, CuGeS, Cu₂Se, CuGeSe, Cu₂Te, and CuGeTe;
(2) the metallic element is silver, and the first ion conductor contains at least one material selected from the group consisting of Ag₂S, AgGeS, Ag₂Se, AgGeSe, Ag₂Te, and AgGeTe.

7. The semiconductor device according to claim 1,
wherein the buried layer contains a second ion conductor which includes a metallic element capable of dissolves into the first ion conductor by an electrochemical reaction, and
the conductive bridge is made of the metallic element.

8. The semiconductor device according to claim 7,
wherein the metallic element is at least one element selected from the group consisting of copper, silver and zinc.

9. The semiconductor device according to claim 7,
wherein the first and second electrodes are independently made of at least one film selected from the group consisting of titanium film, tantalum film, tungsten film, molybdenum film, titanium nitride film, tungsten nitride film, tantalum nitride film, platinum film, metal silicide film, and doped silicon film.

10. The semiconductor device according to claim 7,
wherein the first and second ion conductors are independently made of at least one film selected from the group consisting of tantalum oxide film, zirconium oxide film, niobium oxide film, hafnium oxide film, titanium oxide film, aluminum oxide film, tungsten oxide film, silicon oxide film, sulfur-containing chalcogenide compound film, selenium-containing chalcogenide compound film, and tellurium-containing chalcogenide compound film.

11. The semiconductor device according to claim 7,
wherein the metallic element, the first ion conductor and the second ion conductor meet the following condition (A) or (B):
(A) the metallic element is copper, and the first and second ion conductors independently contain at least one material selected from the group consisting of Cu₂S, CuGeS, Cu₂Se, CuGeSe, Cu₂Te, and CuGeTe;
(B) the metallic element is silver, and the first and second ion conductors respectively contain at least one material selected from the group consisting of Ag₂S, AgGeS, Ag₂Se, AgGeSe, Ag₂Te, and AgGeTe.

12. A semiconductor device, comprising a plurality of the semiconductor elements according to claim 1.

13. The semiconductor device according to claim 12,
wherein a plurality of the resistance changing layers constituting the plurality of the semiconductor elements are separated with each other.

14. The semiconductor device according to claim 12,
wherein a plurality of the resistance changing layers constituting the plurality of the semiconductor elements are connected with each other in region where the semiconductor elements are formed.

15. The semiconductor device according to claim 1,
wherein the conductive bridge reversibly varies between an electric connection state and an electric insulation state on the basis of a polarity of voltage between the first and second electrodes.

16. The semiconductor device according to claim 1,
wherein a width of the upper end of the first electrode is between 3 to 15 nm.

17. A semiconductor device including a semiconductor element, comprising:
a first insulating film, a resistance changing layer containing a first ion conductor, and a second electrode formed in this order;
a buried layer filled up inside of the first insulating film so as to interpose the resistance changing layer between the buried layer and the second electrode; and
a first electrode formed in the first insulating film so as to cover side and bottom surfaces of the buried layer which is not in contact with the resistance changing layer, the first electrode being in contact with the resistance changing layer via an upper end thereof and having a lower electronic resistance than the buried layer,
wherein the semiconductor element changes the electronic resistance between the first and second electrodes by reversibly forming a conductive bridge between the upper end of the first electrode and the second electrode within the resistance changing layer.

18. The semiconductor device according to claim 17,
wherein any one of the first and second electrodes contains a metallic element capable of dissolving into the first ion conductor by an electrochemical reaction, and
the conductive bridge is made of the metallic element.

19. The semiconductor device according to claim 18,
wherein the metallic element is at least one element selected from the group consisting of copper, silver and zinc.

20. The semiconductor device according to claim 17,
wherein the first ion conductor is made of at least one film selected from the group consisting of tantalum oxide film, zirconium oxide film, niobium oxide film, hafnium oxide film, titanium oxide film, aluminum oxide film, tungsten oxide film, silicon oxide film, sulfur-containing chalcogenide compound film, selenium-containing chalcogenide compound film, and tellurium-containing chalcogenide compound film.
